(19) United States
(12) Patent Application Publication
(10) Pub. No.: US 2015/0036416 A1
(43) Pub. Date: Feb. 5, 2015

(54) MULTI-CHANNEL MEMORY DEVICE WITH INDEPENDENT CHANNEL POWER SUPPLY STRUCTURE AND METHOD OF CONTROLLING POWER NET

(71) Applicant: SAMSUNG ELECTRONICS CO., LTD., Suwon-Si (KR)

(72) Inventor: SOO HWAN KIM, Yongin-Si (KR)

(21) Appl. No.: 14/315,002

(22) Filed: Jun. 25, 2014

Related U.S. Application Data
(60) Provisional application No. 61/862,348, filed on Aug. 5, 2013.

(30) Foreign Application Priority Data
Nov. 12, 2013 (KR) 10-2013-0137081

(51) Int. Cl. G11C 5/14; G11C 11/401

(52) U.S. Cl. CPC G11C 5/14; G11C 11/401
USPC 365/149; 365/226

(57) ABSTRACT

A multi-channel memory device includes a first channel memory and a second channel memory that are independently accessible within a same chip and that respectively include first and second power channel connection lines; a decoupling unit that can operationally connect or separate the first and second power channel connection lines in response to a decoupling driving signal; and a switching control unit that can apply the decoupling driving signal to the decoupling unit in response to a channel power control signal such that power supply voltages independently applied to the first and second channel memories are respectively used in corresponding first and second power channel connection lines.

### CROSS-REFERENCE TO RELATED APPLICATIONS

This application claims priority under 35 U.S.C. §119 from U.S. Provisional Application No. 61/862,348 filed Aug. 5, 2013, in the U.S. Patent and Trademark Office, and from Korean Patent Application No. 10-2013-0137081 filed Nov. 12, 2013, in the Korean Intellectual Property Office, and all the benefits accruing therefrom, the contents of both of which are herein incorporated by reference in their entireties.

### BACKGROUND

Embodiments of the inventive concept described herein are directed to a semiconductor memory device, and more particularly, to a multi-channel memory device having channel memories that can be independently accessed within the same chip.

A processing system may include a multi-channel memory device that independently operates through different channels within a chip.

A multi-channel memory device may be formed of a volatile memory such as a DRAM and may include two or more channel memories. The channel memories may be respectively connected to corresponding processors to perform independent data read operations and data write operations.

An external power supply voltage and an internal power supply voltage should be efficiently supplied to a plurality of channel memories of the multi-channel memories.

### SUMMARY

According to an embodiment of the inventive concept, there is provided a multi-channel memory device comprising a first channel memory and a second channel memory that are independently accessible within a same chip and that respectively include first and second external power channel connection lines; a decoupling unit configured to operationally connect or separate first and second external power channel connection lines in response to a decoupling driving signal; and a switching control unit configured to apply the decoupling driving signal to the decoupling unit in response to a channel power control signal such that external power supply voltages independently applied to the first and second channel memories are respectively used in corresponding first and second external power channel connection lines.

In exemplary embodiments, each of the first and second channel memories comprises one of a DRAM cell or an MRAM cell.

In exemplary embodiments, the first and second external power channel connection lines are connected to each other when a corresponding switch of the decoupling unit is closed.

In exemplary embodiments, the first and second external power channel connection lines are separated from each other when a corresponding switch of the decoupling unit is opened.

In exemplary embodiments, when the decoupling unit is activated, the first channel memory and the second channel memory form a power network over the multi-channel memory device.

In exemplary embodiments, the decoupling unit is one of an RC filter or a transmission gate.

In exemplary embodiments, the multi-channel memory device further comprises external power supply pads, in which the first and second external power channel connection lines receive the external supply voltages through the external power supply pads, an external power supply pad is installed for each channel, and the external power supply pads are connected in common to an external power common pad.

According to another embodiment of the inventive concept, there is provided a multi-channel memory device comprising a first channel memory and a second channel memory that are independently accessible within a same chip and that include first and second internal power channel connection lines; first and second internal power generators configured to apply first and second internal power supply voltages that are independent of each other to the first and second channel memories; a decoupling unit configured to operationally connect or separate first and second internal power channel connection lines in response to a decoupling driving signal; and a switching control unit configured to apply the decoupling driving signal to the decoupling unit in response to a channel power control signal such that the first and second internal power supply voltages are respectively used in corresponding first and second internal power channel connection lines.

In exemplary embodiments, each of the first and second internal power generators generates an internal power supply voltage, a high power supply voltage that is greater than the internal power supply voltage, or a substrate power supply voltage that is less than the internal power supply voltage.

In exemplary embodiments, each of the first and second channel memories comprises a plurality of DRAM cells, each having an access transistor and a storage capacitor.

In exemplary embodiments, when a corresponding switch of the decoupling unit is closed, the first and second internal power channel connection lines are connected to each other, and a power network is formed over the first and second channel memories.

In exemplary embodiments, when a corresponding switch of the decoupling unit is opened, the first and second internal power channel connection lines are separated from each other, and the first and second channel memories have independent power networks, respectively.

In exemplary embodiments, a DC component of the first and second internal power supply voltages is shorted, and an AC component of the first and second internal power supply voltages is opened.

In exemplary embodiments, the multi-channel memory device is mounted on a mobile device.

In exemplary embodiments, the channel power control signal is provided as a mode register set signal at power-up of the multi-channel memory device.

According to another embodiment of the inventive concept, there is provided a method of controlling a power network of a multi-channel memory device, the method comprising applying first and second power supply voltages to first and second channel memories of the multi-channel memory device that respectively correspond to the first and second power supply voltages; and operationally separating first and second power networks of the first and second channel memories when a decoupling request signal is generated. Here, the first and second channel memories are independently accessible within a same chip, and the first and second power supply voltages are independent each other.

In exemplary embodiments, the first and second power supply voltages are internal power supply voltages.

In exemplary embodiments, the first and second power supply voltages are external power supply voltages.

In exemplary embodiments, the method comprises operationally connecting the first and second power networks of the first and second channel memories when a decoupling switch is closed. Here, a power network is formed over the first and second channel memories.

### BRIEF DESCRIPTION OF THE FIGURES

FIG. 1 is a schematic block diagram that illustrates a multi-channel memory device according to an embodiment of the inventive concept.

FIG. 2 is a device block diagram of an embodiment of FIG. 1.

FIG. 3 is a device block diagram of another embodiment of FIG. 1.

FIG. 4 is a device block diagram of another embodiment of FIG. 1.

FIG. 5 is a diagram of an embodiment of a decoupling unit of FIG. 1.

FIG. 6 is a diagram of another embodiment of a decoupling unit of FIG. 1.

FIG. 7 is an equivalent circuit diagram of FIG. 5 or 6.

FIG. 8 is a circuit block diagram of a channel memory of FIG. 1.

FIGS. 9A to 9D are diagrams that illustrate applications of embodiments of the inventive concept to a memory system having various interfaces.

FIG. 10 is a schematic diagram that illustrates an application of an embodiment of the inventive concept to a memory system stacked through through-silicon via (TSV).

FIG. 11 is a schematic block diagram that illustrates an application of an embodiment of the inventive concept to an electronic system.

FIG. 12 is a schematic block diagram that illustrates an application of an embodiment of the inventive concept to a computing device.

FIG. 13 is a schematic block diagram that illustrates an application of an embodiment of the inventive concept to a portable telephone.

FIG. 14 is a schematic block diagram that illustrates an application of an embodiment of the inventive concept to a mobile device.

FIG. 15 is a schematic block diagram that illustrates an application of an embodiment of the inventive concept to an optical I/O scheme.

FIG. 16 is a schematic block diagram that illustrates an application of an embodiment of the inventive concept to a portable multimedia device.

FIG. 17 is a schematic block diagram that illustrates an application of an embodiment of the inventive concept to a personal computer.

### DETAILED DESCRIPTION

Exemplary embodiments will be described in detail with reference to the accompanying drawings. The inventive concept, however, may be embodied in various different forms, and should not be construed as being limited only to the illustrated embodiments. Unless otherwise noted, like reference numerals may denote like elements throughout the attached drawings and written description, and thus descriptions will not be repeated. In the drawings, the sizes and relative sizes of layers and regions may be exaggerated for clarity.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present.

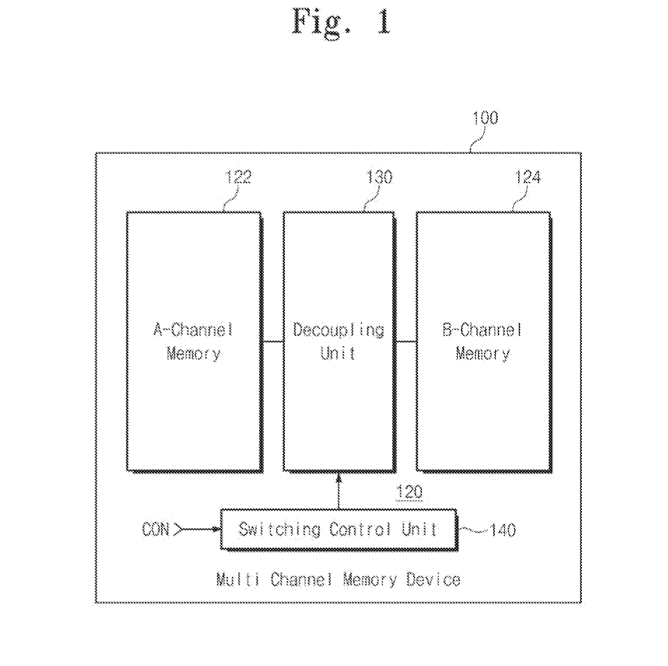

FIG. 1 is a schematic block diagram that illustrates a multi-channel memory device according to an embodiment of the inventive concept.

Referring to FIG. 1, a multi-channel memory device 100 may include a multi-channel memory 120 and a switching control unit 140.

The multi-channel memory 120 may include a first channel memory 122 and a second channel memory 124 which are independently accessed in the same chip. That is, the multi-channel memory 120 may include two or more channel memories, each of which is formed of a DRAM or a magnetoresistive random-access memory (MRAM). For ease of description, the first and second channel memories 122 and 124 may be shown as an A-channel memory and a B-channel memory in FIG. 1.

Each channel memory may receive an address, data, and a command through an independent channel.

If the multi-channel memory 120 includes two channel memories, a decoupling unit 130 may be installed between the channel memories. The decoupling unit 130 may operationally separate first and second power channel connection lines of the first and second channel memories 122 and 124 in response to a decoupling driving signal. A DC current may be shorted due to characteristics of an operating frequency of the decoupling unit 130, and an AC current, such as power noise, may be opened from characteristics of an operating frequency of the decoupling unit 130.

When the decoupling unit 130 is activated, the first and second channel memories 122 and 124 may form a power network over the multi-channel memory device 100 or a power network may independently form from the number of channels.

The switching control unit 140 may apply the decoupling driving signal to the decoupling unit 130 in response to a channel power control signal CON so that power independently applied to the first and second channel memories 122 and 124 are respectively used within corresponding channels.

It may be assumed that in the event that a power network is not independent of a channel, the first channel memory 122 performs a refresh operation, and the second channel memory 124 carries out a write operation. During a refresh operation, all banks of the first channel memory 122 may experience active and pre-charge operations. In this case, the consumption of a high power supply voltage, which is a word line voltage, may cause noise in the first channel memory 122. In addition, the first channel memory 122 may consume an array voltage when cell data is restored. Although a refresh cycle time is longer than a write or read time, noise generated in the refresh operation may affect a write or read operation of the second channel memory 124. On the other hand, noise generated in the write operation of the second channel memory 124 may affect the refresh operation of the first channel memory 122, which may hinder restoring cell data.

Thus, the decoupling unit 130 may be selectively controlled so that a power network may be independent of a channel.

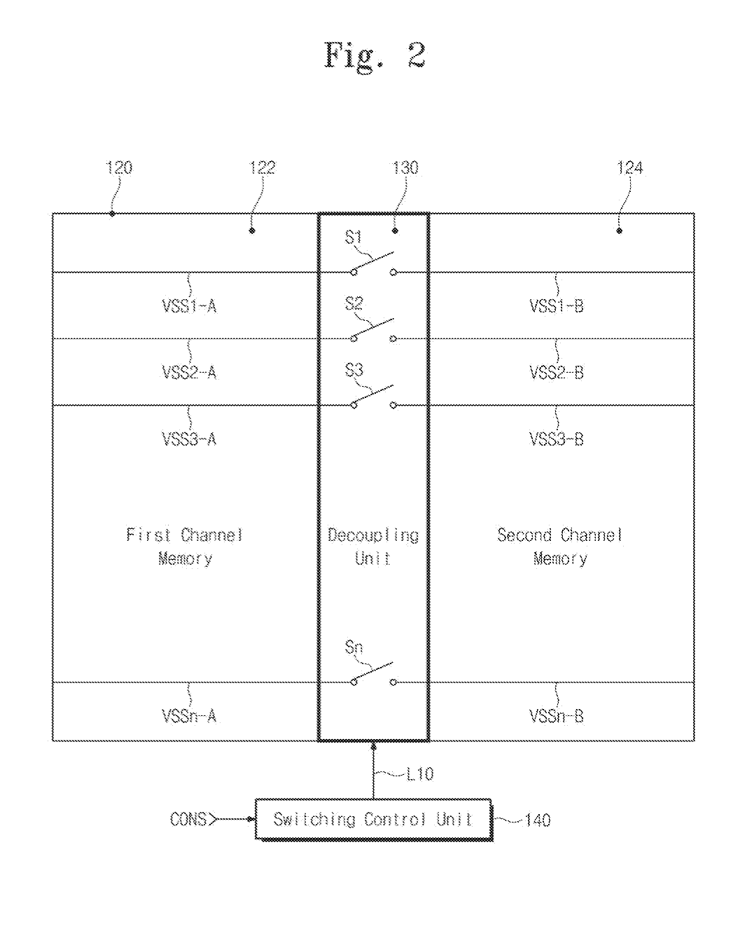

FIG. 2 is a device block diagram of an embodiment of FIG. 1.

FIG. 2 illustrates a connection structure of a power network of a ground voltage VSS of external power supply voltages of a multi-channel memory 120 that includes first and second channel memories 122 and 124. The first external power channel connection lines of a first channel memory 122 may include first to nth channel connection lines VSS1-A, VSS2-A . . . and VSSn-A. Here, “n” may be a positive integer that greater than or equal to 2. The first to nth channel connection lines VSS1-A, VSS2-A . . . and VSSn-A may receive the ground voltage VSS through an external power supply pad.

The second external power channel connection lines of the second channel memory 124 may include first to nth channel connection lines VSS1-B, VSS2-B . . . and VSSn-B. Likewise, the first to nth channel connection lines VSS1-B, VSS2-B . . . and VSSn-B may receive the ground voltage VSS through an external power supply pad.

The decoupling unit 130 may include first to nth switches S1, S2, . . . , Sn. If a first switch S1 of the decoupling unit 130 is opened, the first channel connection line VSS1-A of a first external power supply voltage of the first channel memory 122 may be operationally separated from the first channel connection line VSS1-B of a second external power supply voltage of the second channel memory 124. In this case, two power networks may be formed independent of the channels.

On the other hand, if the first switch S1 of the decoupling unit 130 is closed, the first channel connection line VSS1-A of the first external power supply voltage of the first channel memory 122 may be operationally connected to the first channel connection line VSS1-B of the second external power supply voltage of the second channel memory 124. In this case, one power network may be formed over the channels.

Similarly, when an nth switch Sn of the decoupling unit 130 is opened, the nth channel connection line VSSn-A of the first external power supply voltage of the first channel memory 122 may be operationally separated from the nth channel connection line VSSn-B of the second external power supply voltage of the second channel memory 124.

On the other hand, if the nth switch Sn of the decoupling unit 130 is closed, the nth channel connection line VSSn-A of the first external power supply voltage of the first channel memory 122 may be operationally connected to the nth channel connection line VSSn-B of the second external power supply voltage of the second channel memory 124.

Accordingly, the decoupling unit 130 connected between the channel memories 122 and 124 may perform a decoupling operation based on a decoupling driving signal that is applied to a line L10. In response to a signal state of the decoupling driving signal that indicates opening a switch, the decoupling unit 130 may operationally separate a pair of first and second external power channel connection lines, such as VSS1-A and VSS1-B, disposed between the first and second channel memories 122 and 124.

In response to a signal state of the decoupling driving signal that indicates closing a switch, the decoupling unit 130 may operationally connect a pair of first and second external power channel connection lines, such as VSS1-A and VSS1-B, disposed between the first and second channel memories 122 and 124.

In FIG. 2, a switching control unit 140 may apply the decoupling driving signal to the decoupling unit 130 in response to a channel power control signal CONS so that external power supply voltages VSSA and VSSB independently applied to the first and second channel memories 122 and 124 are respectively used within corresponding channels. The channel power control signal CONS may be provided to a multi-channel memory device 100 as a mode register set signal after power-up.

As shown in FIG. 2, a power network of an external power supply voltage or power networks of the external power supply voltage that correspond to the number of channels may be formed due to a decoupling operation of the decoupling unit 130.

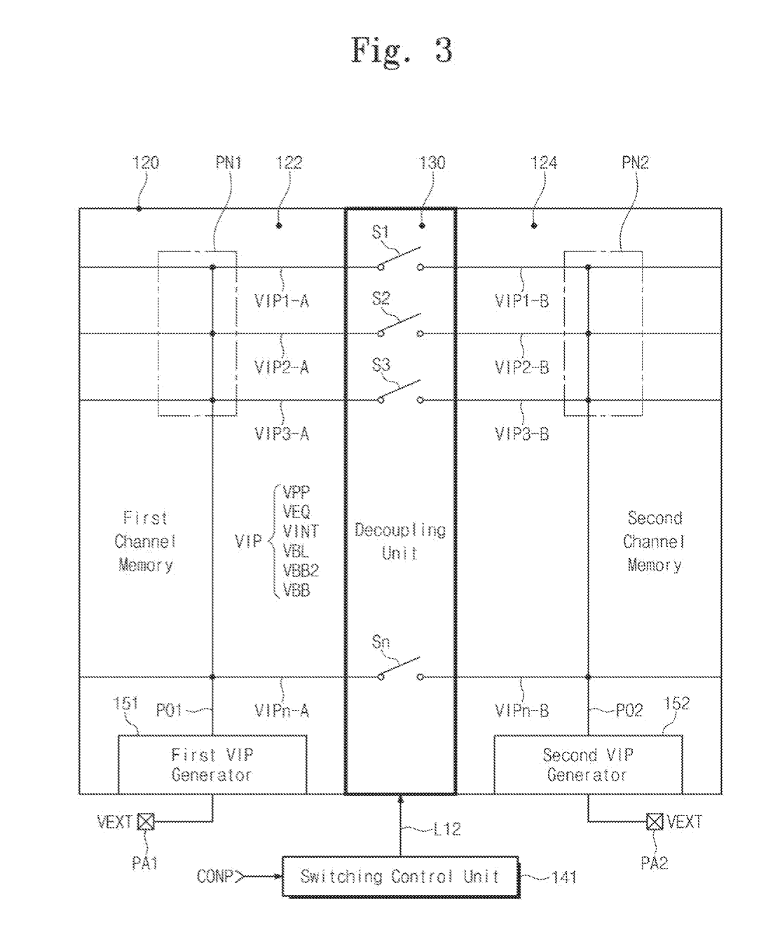

FIG. 3 is a device block diagram of another embodiment of FIG. 1.

Referring to FIG. 3, a multi-channel memory device 100 may include a multi-channel memory 120 and a switching control unit 141.

The multi-channel memory 120 may include a first channel memory 122 and a second channel memory 124, which are independently accessed in the same chip. That is, the multi-channel memory 120 may include two or more channel memories, each of which is formed of a DRAM or an MRAM. The first and second channel memories 122 and 124 may include internal power networks, respectively. Like FIG. 1, each channel memory may receive an address, data, and a command to be independent of a channel.

If the multi-channel memory 120 includes two channel memories, a decoupling unit 130 may be installed between the channel memories. The decoupling unit 130 may operationally separate first and second external power channel connection lines, such as VIP1-A and VIP2-B, of the first and second channel memories 122 and 124 in response to a decoupling driving signal applied through a line L12.

When the decoupling unit 130 is activated, an internal power network may be formed for each of the first and second channel memories 122 and 124 over the multi-channel memory device 100 or may be independently formed by the number of channels.

The switching control unit 141 may apply the decoupling driving signal to the decoupling unit 130 in response to a channel power control signal CONP so that the first and second internal power supply voltages independently applied to the first and second channel memories 122 and 124 are respectively used within corresponding channels.

FIG. 3 illustrates an independent internal power network. Thus, unlike FIG. 2, first and second internal power generators 151 and 152 may be installed within the multi-channel memory 120.

That is, the first and second internal power generators 151 and 152 may respectively and independently apply the first and second internal power supply voltages to the first and second channel memories 122 and 124. For example, the first internal power supply voltage VIPA may be supplied to a first power network PN1 through a first channel power supply line PO1, and the second internal power supply voltage VIPB may be supplied to a second power net PN2 through a second channel power supply line PO2. Here, a voltage level of the first internal power supply voltage VIPA may be equal to that of the second internal power supply voltage VIPB. If the first internal power generator 151 is a high-voltage pump circuit, it may pump charges in response to an external power supply voltage VEXT applied to a pad PA1. The voltage thus pumped may be provided to the first power net PN1 of the first channel memory 122 as a high power supply voltage VPP.

In addition, if the second internal power generator 152 is a high-voltage pump circuit, it may pump charges in response to an external power supply voltage VEXT applied to a pad PA2. The voltage thus pumped may be provided to the second power net PN2 of the second channel memory 124 as a high power supply voltage VPP.

FIG. 3 shows a connection structure of an internal power network of a multi-channel memory 120 that has two channels. The first internal power channel connection lines of the first channel memory 122 may include first to nth channel connection lines VIP1-A, VIP2-A . . . and VIPn-A. Here, “n” may be a positive integer greater than or equal to 2. The first to nth channel connections VIP1-A, VIP2-A . . . and VIPn-A may receive a first internal voltage VIP-A through the first channel power supply line PO1. Here, the first internal voltage VIP-A may be an internal power supply voltage VINT, a high power supply voltage VPP that is greater than the internal power supply voltage VINT, or a substrate power supply voltage VBB that is less than the internal power supply voltage VINT. In addition, the first internal voltage VIP-A may be a voltage VEQ that is less than the internal power supply voltage VINT, half-level voltage VBL of the internal power supply voltage VINT, or a second substrate power supply voltage VBB2 that is greater than the substrate power supply voltage VBB.

The second internal power channel connection lines of the second channel memory 124 may include first to nth channel connection lines VIP1-B, VIP2-B . . . and VIPn-B. Likewise, the first to nth channel connections VIP1-B, VIP2-B . . . and VIPn-B may receive a second internal voltage VIP-B through the second channel power supply line PO2. Here, the second internal voltage VIP-B may be the internal power supply voltage VINT, the high power supply voltage VPP that is greater than the internal power supply voltage VINT, or the substrate power supply voltage VBB that is less than the internal power supply voltage VINT. In addition, the second internal voltage VIP-B may be the voltage VEQ that is less than the internal power supply voltage VINT, the half-level voltage VBL of the internal power supply voltage VINT, or the second substrate power supply voltage VBB2 that is greater than the substrate power supply voltage VBB.

The decoupling unit 130 may include first to nth switches S1, S2, . . . , Sn. If a first switch S1 of the decoupling unit 130 is opened, the first channel connection line VIP1-A of a first internal power supply voltage of the first channel memory 122 may be operationally separated from the first channel connection line VIP1-B of a second internal power supply voltage of the second channel memory 124. In this case, two power networks PN1 and PN2 may be formed independent of a channel.

On the other hand, if the first switch S1 of the decoupling unit 130 is closed, the first channel connection line VIP1-A of the first internal power supply voltage of the first channel memory 122 may be operationally connected to the first channel connection line VIP1-B of the second internal power supply voltage of the second channel memory 124. In this case, the first and second power networks PN1 and PN2 may form a power network over the multi-channel memory 120.

Similarly, when an nth switch Sn of the decoupling unit 130 is opened, the nth channel connection line VIPn-A of the first internal power supply voltage of the first channel memory 122 may be operationally separated from the nth channel connection line VIPn-B of the second internal power supply voltage of the second channel memory 124.

On the other hand, if the nth switch Sn of the decoupling unit 130 is closed, the nth channel connection line VIPn-A of the first internal power supply voltage of the first channel memory 122 may be operationally connected to the nth channel connection line VIPn-B of the second internal power supply voltage of the second channel memory 124.

Accordingly, the decoupling unit 130 connected between the channel memories 122 and 124 may perform a decoupling operation based on a decoupling driving signal that is applied to a line L12. In response to a signal state of the decoupling driving signal that indicates opening a switch, the decoupling unit 130 may operationally separate first and second internal power channel connection lines, such as VIP1-A and VIP1-B, disposed between the first and second channel memories 122 and 124.

In response to a signal state of the decoupling driving signal that indicates closing a switch, the decoupling unit 130 may operationally connect first and second internal power channel connection lines, such as VIP1-A and VIP1-B, disposed between the first and second channel memories 122 and 124.

In FIG. 3, a switching control unit 141 may apply the decoupling driving signal to the decoupling unit 130 in response to a channel power control signal CONP so that external power supply voltages VIP-A and VIP-B independently applied to the first and second channel memories 122 and 124 are respectively used within corresponding channels. The channel power control signal CONP may be provided to a multi-channel memory device 100 as a mode register set signal after power-up.

As shown in FIG. 3, a power network of an internal power supply voltage or power networks of the internal power supply voltage that correspond to the number of channels may be formed based on a decoupling operation of the decoupling unit 130.

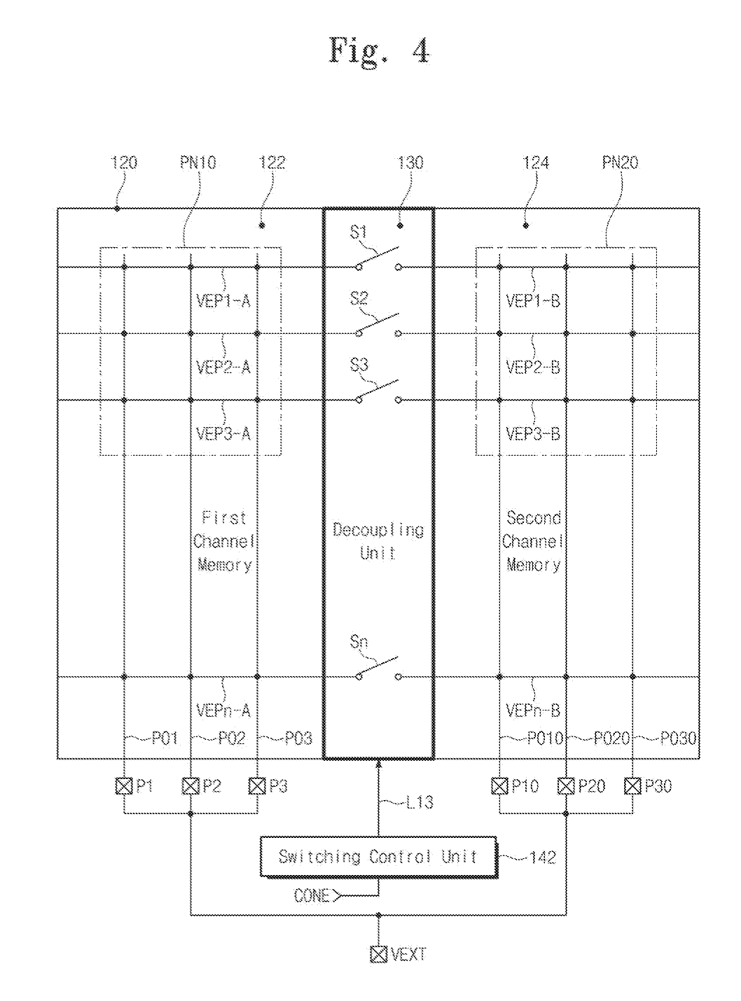

FIG. 4 is a device block diagram of another embodiment of FIG. 1.

FIG. 4 illustrates a connection structure of a power network of external power supply voltages of a multi-channel memory 120 that include first and second channel memories 122 and 124. The first external power channel connection lines of a first channel memory 122 may include first to nth channel connection lines VEP1-A, VEP2-A . . . and VEPn-A. Here, “n” may be a positive integer greater than or equal to 2. The first to nth channel connection lines VEP1-A, VEP2-A . . . and VEPn-A may receive an external power supply voltage VEP through external power supply pads P1, P2, and P3. All or a part of the first to nth channel connection lines VEP1-A, VEP2-A . . . and VEPn-A may form a power network PN10 for a first external power supply voltage.

The second external power channel connection lines of a second channel memory 124 may include first to nth channel connection lines VEP1-B, VEP2-B . . . and VEPn-B. Here, “n” may be a positive integer greater than or equal to 2. The first to nth channel connection lines VEP1-B, VEP2-B . . . and VEPn-B may receive the external power supply voltage VEP through external power supply pads P10, P20, and P30. All or a part of the first to nth channel connection lines VEP1-B, VEP2-B . . . and VEPn-B may form a power network PN20 for the first external power supply voltage.

The external power supply pads P1, P2, and P3 of the first channel and the external power supply pads P10, P20, and P30 of the second channel may be installed for every channel, and they may be connected in common to an external power common pad VEXT on a PCB.

If a first switch S1 of a decoupling unit 130 is opened, the first channel connection line VEP1-A of a first external power supply voltage of the first channel memory 122 may be operationally separated from the first channel connection line VEP1-B of a second external power supply voltage of the second channel memory 124. In this case, two power networks PN10 and PN20 may be formed independent of a channel.

If the first switch S1 of the decoupling unit 130 is closed, the first channel connection line VEP1-A of the first external power supply voltage of the first channel memory 122 may be operationally connected to the first channel connection line VEP1-B of the second external power supply voltage of the second channel memory 124. In this case, two power networks PN10 and PN20 may be operationally connected to each other to form a common power network.

Similarly, when an nth switch Sn of the decoupling unit 130 is opened, an nth channel connection line VEPn-A of the first external power supply voltage of the first channel memory 122 may be operationally separated from an nth channel connection line VEPn-B of the second external power supply voltage of the second channel memory 124.

On the other hand, when the nth switch Sn of the decoupling unit 130 is opened, the nth channel connection line VEPn-A of the first external power supply voltage of the first channel memory 122 may be operationally connected to the nth channel connection line VEPn-B of the second external power supply voltage of the second channel memory 124.

Accordingly, the decoupling unit 130 connected between the channel memories 122 and 124 may perform a decoupling operation based on a decoupling driving signal that is applied to a line L13. In response to a signal state of the decoupling driving signal that indicates opening a switch, the decoupling unit 130 may operationally separate first and second external power channel connection lines, such as VEP1-A and VEP1-B, disposed between the first and second channel memories 122 and 124.

On the other hand, in response to a signal state of the decoupling driving signal that indicates closing a switch, the decoupling unit 130 may operationally connect first and second external power channel connection lines, such as VEP1-A and VEP1-B, disposed between the first and second channel memories 122 and 124.

In FIG. 4, a switching control unit 142 may apply the decoupling driving signal to the decoupling unit 130 in response to a channel power control signal CONE so that external power supply voltages VEPA and VEPB independently applied to the first and second channel memories 122 and 124 are respectively used within corresponding channels. The channel power control signal CONE may be provided to a multi-channel memory device 100 as a mode register set signal after power-up.

As shown in FIG. 4, a power network of an external power supply voltage or power networks of the external power supply voltage that correspond to the number of channels may be formed based on a decoupling operation of the decoupling unit 130.

In FIG. 4, the external power supply voltage VEP may include a ground voltage. In addition, the external power supply voltage VEP may include the external power supply voltage VEXT, an external voltage, an external voltage for input/output, a ground voltage for input/output, or an external voltage for input/output.

As above described, a power network may be formed. In this case, an operation may be secured independently for every channel, and power noise interference between channels may be minimized or removed. In addition, in some cases, a power network may be formed for all channels.

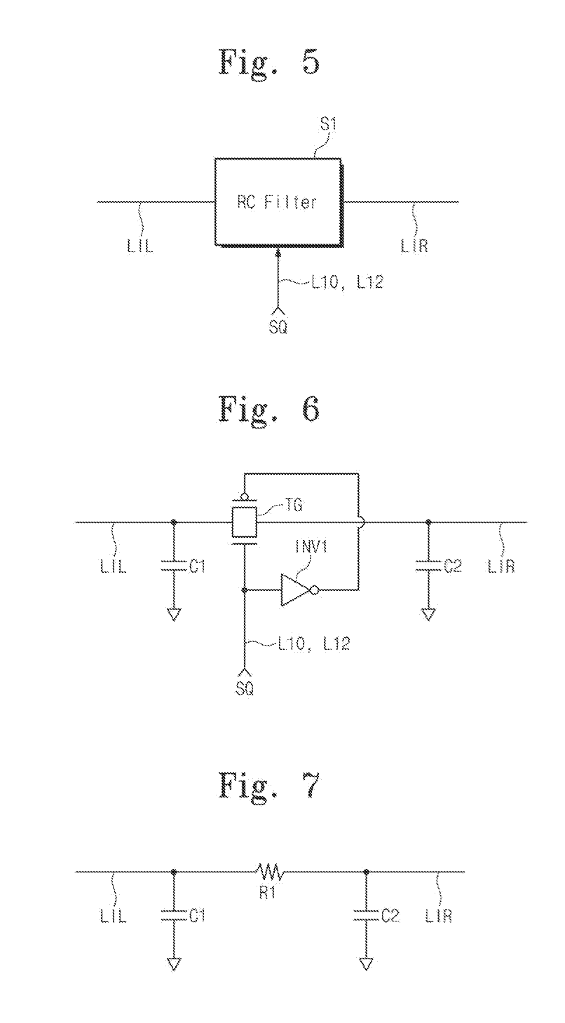

FIG. 5 is a diagram of an embodiment of a decoupling unit of FIG. 1.

Referring to FIG. 5, a decoupling unit 130 may be implemented by an RC filter S1.

The RC filter S1 may operate in response to a signal SQ applied as a decoupling driving signal. The RC filter S1 may selectively act as an integrator according to a state of the signal SQ.

If the RC filter S1 is enabled, a first power line LIL and a second power line LIR may be operationally connected to each other. On the other hand, when the RC filter S1 is disabled, the first power line LIL and the second power line LIR may be operationally separated from each other. Here, the first and second power lines LIL and LIR may correspond to first and second external power channel connection lines (e.g., VSS1-A and VSS1-B) shown in FIG. 2.

FIG. 6 is a diagram of another embodiment of a decoupling unit of FIG. 1.

Referring to FIG. 6, a decoupling unit 130 may be implemented by a transmission gate TG.

The transmission gate TG may operate in response to a signal SQ applied as a decoupling driving signal. The transmission gate TG may selectively perform a power transfer function according to a logical state of the signal SQ.

If the transmission gate TG is enabled in response to the signal SQ being high, a first power line LIL and a second power line LIR may be operationally connected to each other. On the other hand, if the transmission gate TG is disabled in response to the signal SQ being low, the first power line LIL and the second power line LIR may be operationally separated from each other. Here, the first and second power lines LIL and LIR may correspond to first and second external power channel connection lines (e.g., VIP1-A and VIP1-B) shown in FIG. 3.

In FIG. 6, capacitors C1 and C2 may be respectively connected to the first and second power lines LIL and LIR to filter noise. The decoupling unit 130 may also include an inverter INV1 which inverts a logical level of the signal SQ to drive a PMOS transistor of the transmission gate TG.

FIG. 7 is an equivalent circuit diagram of FIGS. 5 and 6.

FIG. 7 shows a structure in which a resistance R1 and first and second capacitors C1 and C2 are connected between a first power line LIL and a second power line LIR.

A value of the first resistance R1 may be variable, and the first resistance R1 may correspond to a transmission gate TG shown in FIG. 6.

The first resistance R1 is in a low resistance state when the transmission gate TG is enabled, which may allow the first power line LIL and the second power line LIR to be operationally connected to each other. On the other hand, the first resistance R1 is in a high resistance state when the transmission gate TG is disabled, which may operationally disconnect the first power line LIL and the second power line LIR from each other. The first resistance R1 and the first capacitor C1 may constitute an RC filter to filter power noise. The first resistance R1 and the second capacitor C2 may constitute another RC filter to filter power noise.

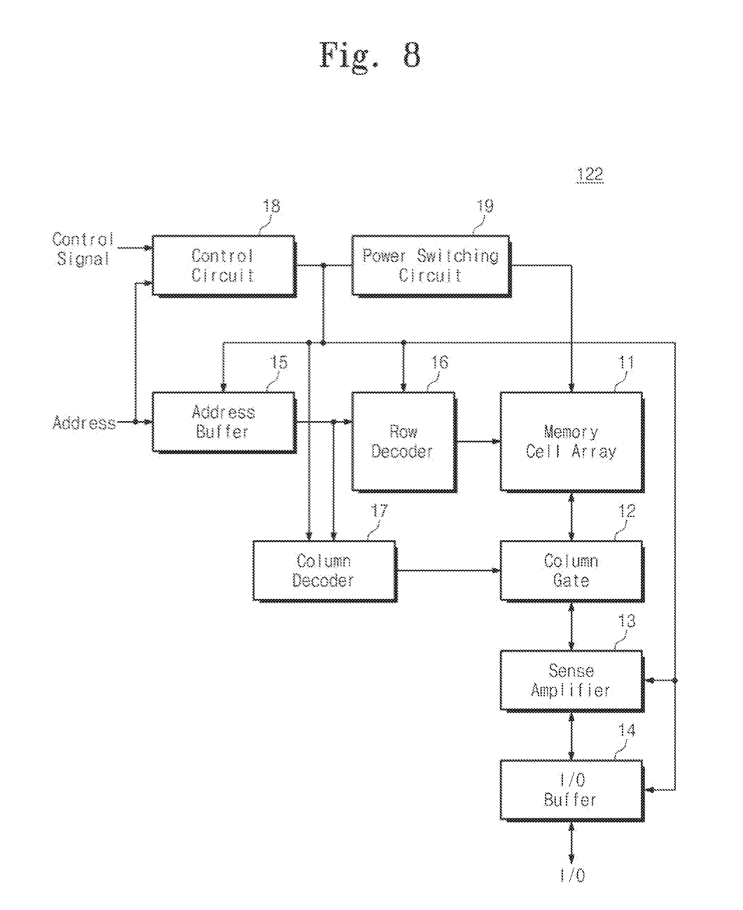

FIG. 8 is a circuit block diagram of a channel memory of FIG. 1.

A first channel memory 122 or a second channel memory 124 may have a circuit block structure shown in FIG. 8.

In FIG. 8, a channel memory 122 may include a memory cell array 11, a column gate 12, a sense amplifier circuit 13, an I/O buffer 14, an address buffer 15, a row decoder 16, a column decoder 17, a control circuit 18, and a power switching circuit 19.

The memory cell array 11 may include DRAM memory cells that each comprise an access transistor and a storage capacitor. The memory cells may be arranged in a matrix structure of rows and columns.

The control circuit 18 may receive a control signal and an address to generate an internal control signal for determining and controlling an operation mode.

The power switching circuit 19 may connect or separate power networks of the channel memory 122 in response to the internal control signal.

The address buffer 15 may receive and buffer an address. In response to the internal control signal, the address buffer 15 may provide the row decoder 16 with a row address for selecting a row of the memory cell array 11 and the column decoder 17 with a column address for selecting a column of the memory cell array 11.

The row decoder 16 may decode the row address in response to the internal control signal. Applying the decoding result of the row address to the memory cell array 11 selects a word line from a plurality of word lines connected to the memory cells.

The column decoder 17 may decode the column address in response to the internal control signal.

The column gate 12 may perform a column gating operation based on the decoded column address to select a bit line from a plurality of bit lines connected to the memory cells.

The sense amplifier circuit 13 may detect data stored in a selected memory cell by detecting a potential on the selected bit line.

The I/O buffer 14 may buffer input/output data. During a read operation, the I/O buffer 14 may buffer data read out from the sense amplifier circuit 13 and may output it to an I/O terminal.

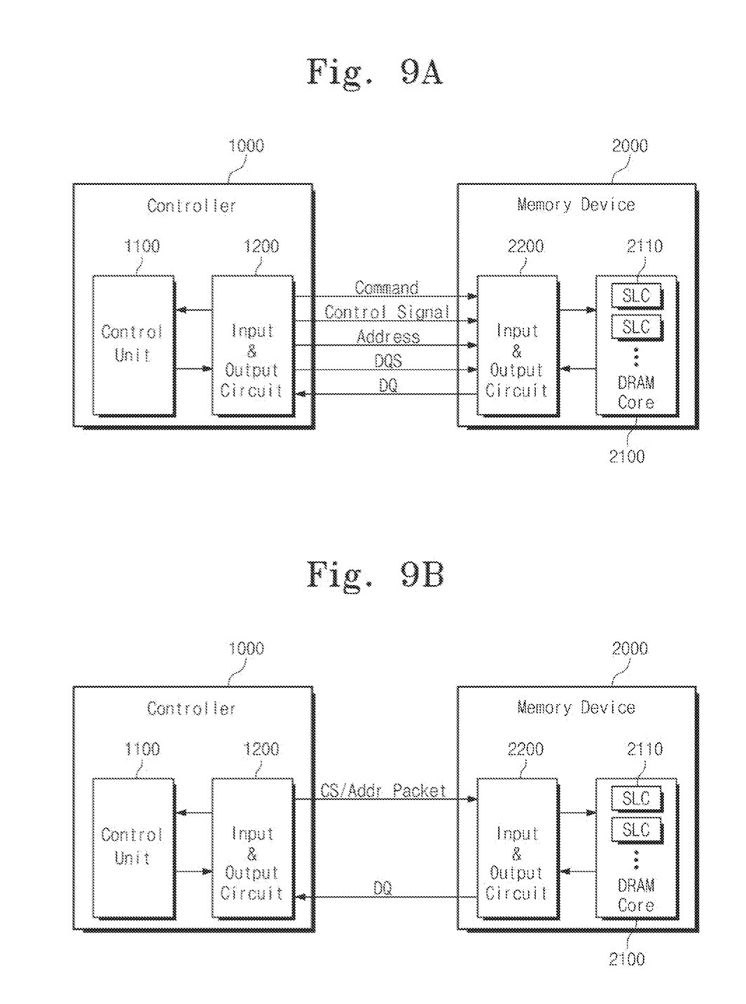

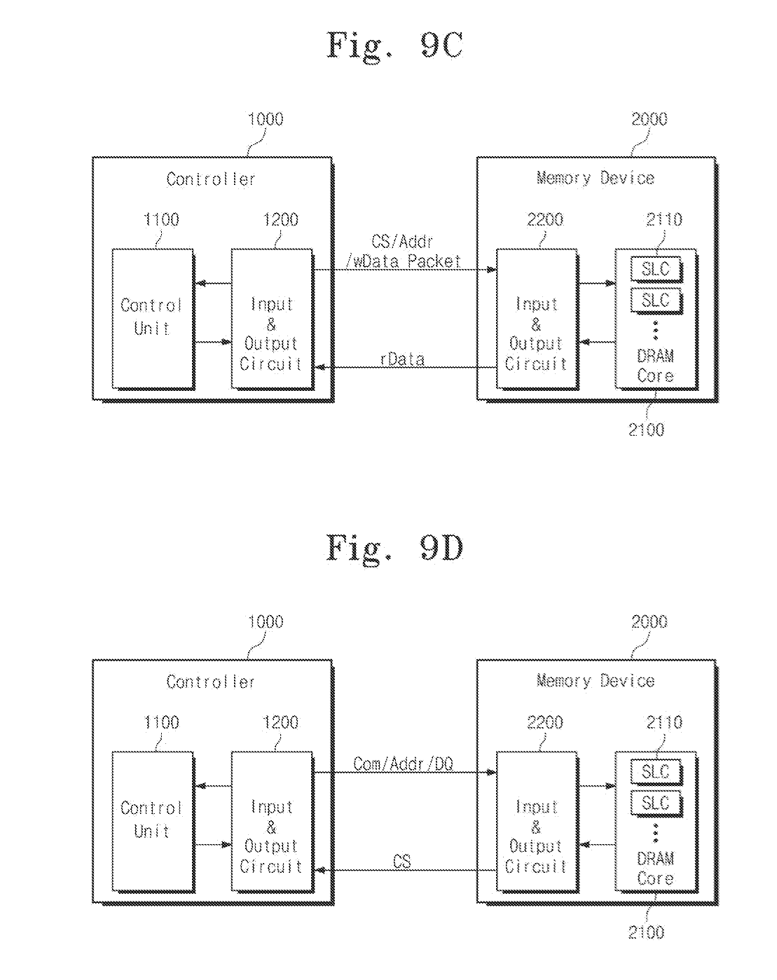

FIGS. 9A to 9D are diagrams that illustrate applications of embodiments of the inventive concept to a memory system having various interfaces.

Referring to FIG. 9A, a memory system may include a controller 1000 and a memory device 2000. The controller 1000 may include a control unit 1100 and an input and output circuit 1200. The memory device 2000 may include a DRAM core 2100 having a sensing and latch circuit SLC 2110 and an input and output circuit 2200. The input and output circuit 1200 of the controller 1000 may include an interface that sends a command, a control signal, an address, and a data strobe signal DQS to the memory device 2000 and receives and sends data DQ. Here, the DRAM core 2100 may be implemented by a multi-channel memory device shown in FIG. 1. Thus, an external power net or an internal power net may be implemented to be independent of a channel or to be shared.

Referring to FIG. 9B, the input and output circuit 1200 of the controller 1000 may include an interface that sends a packet including a chip selection signal CS and an address and transmits and receives data DQ.

Referring to FIG. 9C, the input and output circuit 1200 of the controller 1000 may include an interface that sends a packet including a chip selection signal CS, an address and write data wData and receives read data rData.

Referring to FIG. 9D, the input and output circuit 1200 of the controller 1000 may include an interface that transmits and receives a command, an address, and data DQ and receives a chip selection signal CS.

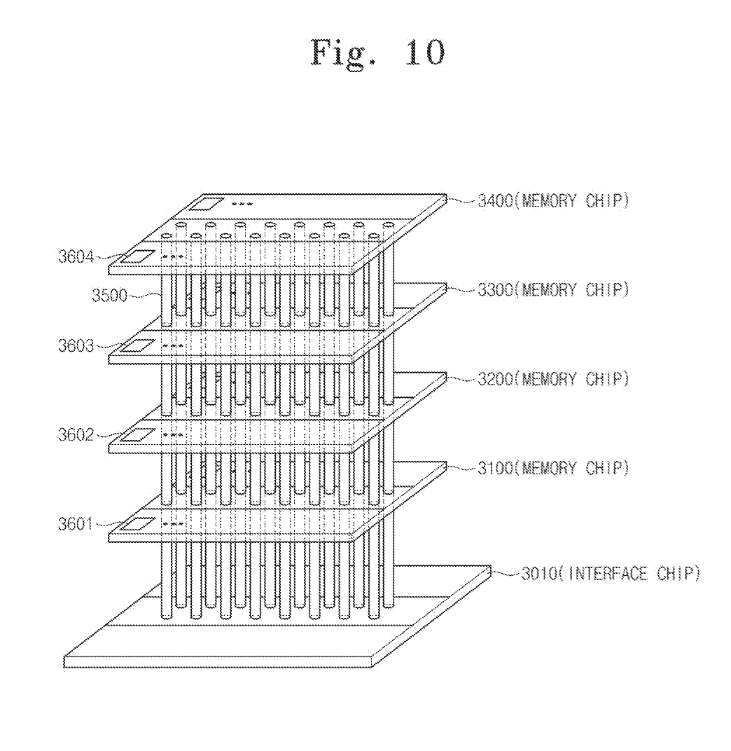

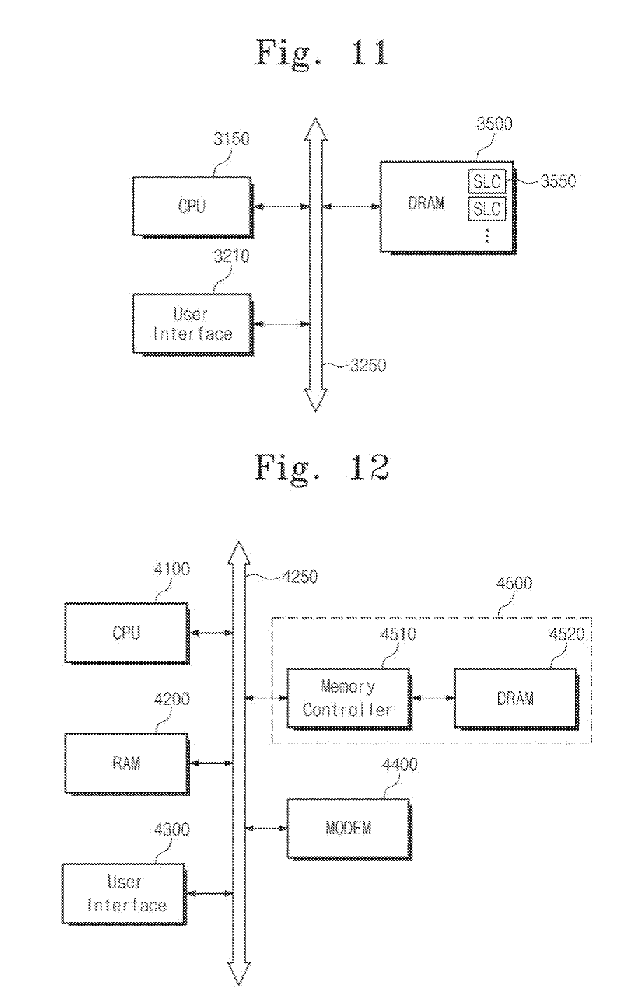

FIG. 10 is a schematic diagram that illustrates an application of an embodiment of the inventive concept to a memory system stacked through through-silicon via (TSV).

Referring to FIG. 10, an interface chip 3010 may be placed on a lowermost layer, and memory chips 3100, 3200, 3300, and 3400 may be placed on the interface chip 3010. The memory chips 3100, 3200, 3300, and 3400 may include sensing and latch circuits 3601, 3602, 3603, and 3604 of embodiments of the inventive concept, respectively. Adjacent chips may be connected through micro bumps 3500, and a chip itself may be connected through through-silicon via (TSV). For example, the number of chips stacked may be 1 or more.

In FIG. 10, each of the memory chips 3100, 3200, 3300, and 3400 may be respectively implemented by a multi-channel memory device such as that shown in FIG. 1.

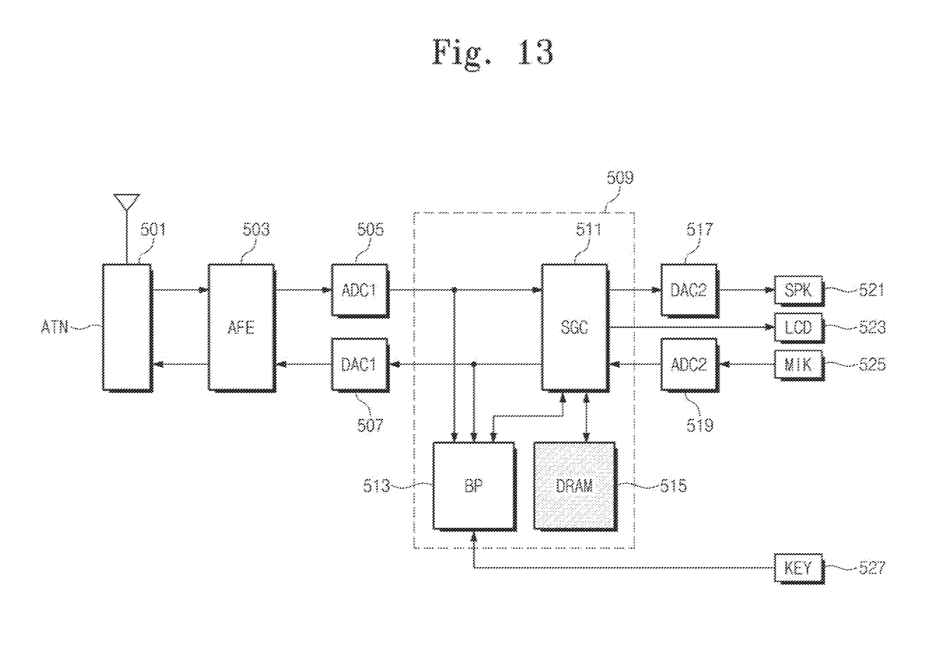

FIG. 11 is a schematic block diagram that illustrates an application of an embodiment of the inventive concept to an electronic system.

Referring to FIG. 11, a DRAM 3500 including a data read circuit 3550, a central processing unit (CPU) 3150, and a user interface 3210 may be connected to a system bus 3250.

If the electronic system is a portable electronic device, there may be a separate interface connected to an external communication device. The communication device may be a DVD (Digital Versatile Disc) player, a computer, a STB (Set Top Box), a game machine, a digital camcorder, etc.

The DRAM chip 3500 or the CPU chip 3150 may be packaged according to any of a variety of different packaging technologies. Examples of such packaging technologies may include Package on Package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), etc.

In FIG. 11, a flash memory may be further connected to the bus 3250. However, embodiments of the inventive concept are not limited thereto. For example, a variety of nonvolatile storages may be used.

A nonvolatile storage may store data information in various data formats, such as a text, graphics, software code, etc.

FIG. 12 is a schematic block diagram that illustrates an application of an embodiment of the inventive concept to a computing device.

Referring to FIG. 12, a computing device may include a memory system 4500 that includes a DRAM 4520 and a memory controller 4510. The computing device may include an information processing device or a computer.

For example, the computing device may include the memory system 4500, a MODEM 4400, a CPU 4100, a RAM 4200, and a user interface 4300 that are electrically connected to a system bus 4250. Data processed by the CPU 4100 or data received from an external device may be stored in the memory system 4500.

The computing device may be used with a solid state disk, a camera image sensor, an application chipset, etc. For example, the memory system 4500 may be formed of a solid state drive (SSD). In this case, the computing device may stably and reliably store mass data in the memory system 4500.

The DRAM 4520 of the memory system 4500 may be implemented by a multi-channel memory device such as that shown in FIG. 1. Thus, the performance of the computing device may be improved.

The memory controller 4510 may provide the DRAM 4520 with a command, an address, data, and a control signal to be independent of a channel.

The CPU 4100 may function as a host and may control an overall operation of the computing device.

A host interface between the CPU 4100 and the memory controller 4510 may include a variety of protocols for data exchange between the memory controller 2000 and the host. The memory controller 2000 may be configured to communicate with the host or an external device using at least one of various protocols such as the USB (Universal Serial Bus) protocol, the MMC (Multi Media Card) protocol, the PCI (Peripheral Component Interconnection) protocol, the PCI-E (PCI-Express) protocol, the ATA (Advanced Technology Attachment) protocol, the Serial-ATA protocol, the Parallel-ATA protocol, the SCSI (Small Computer Small Interface) protocol, the ESDI (Enhanced Small Disk Interface) protocol, and the IDE (Integrated Drive Electronics) protocol.

A device such as that shown in FIG. 12 may be provided as one of various components of an electronic device such as a computer, a ultra-mobile personal computer (UMPC), a digital video recorder, a digital video player, storage for a data center, a device for transmitting and receiving information in a wireless environment, one of the various electronic devices constituting a home network, one of the various electronic devices constituting a computer network, one of the various electronic devices constituting a telematics network, a radio frequency identification (RFID) device, and one of the various components constituting a computing system.

FIG. 13 is a schematic block diagram that illustrates an application of an embodiment of the inventive concept to a portable telephone.

FIG. 13 illustrates the main blocks of a portable telephone, such as a smart phone, that includes a DRAM. The portable telephone may include an antenna (ATN) 501, an analog front end block (AFE) 503, analog-to-digital converters (ADC1, ADC2) 505 and 519, digital-to-analog converters (DAC1, DAC2) 507 and 517, a baseband block 509, a speaker (SPK) 521, a liquid crystal monitor (LCD) 523, a microphone (MIK) 525, and an input key (KEY) 527. The analog front end block 503 may be a circuit that includes an antenna switch, a band pass filter, various amplifiers, a power amplifier, a phase locked loop, a voltage controlled oscillator, an orthogonal demodulator, an orthogonal modulator, etc. and may transmit and receive radio waves. The baseband block 509 may include a signal processing circuit (SGC) 511, a baseband processor (BP) 513, and a DRAM 515.

Below, an operation of a portable telephone will be described with reference to FIG. 13. When an image that includes voice and character information is received, a radio wave received from the antenna may be provided to the analog-to-digital converter 505 through the analog front end block 503 for waveform equalization and analog-to-digital conversion. An output signal of the analog-to-digital converter 505 may be provided to the signal processing circuit 511 of the baseband block 509 for voice and image processing. A voice signal may be transferred to the speaker 521 through the digital-to-analog converter 517, and an image signal may be transferred to the liquid crystal monitor 523.

If a voice signal is transmitted, a signal received from the microphone 525 may be provided to the signal processing circuit 511 through the analog-to-digital converter 519 for voice processing. An output of the signal processing circuit 511 may be transferred to the antenna 501 through the digital-to-analog converter 507 and the analog front end block 503. If character information is transmitted, a signal received from the input key 527 may be provided to the antenna 501 through the baseband block 509, the digital-to-analog converter 507, and the analog front end block 503.

In FIG. 13, the DRAM 515 may be implemented by a multi-channel memory device such as that shown in FIG. 1. In this case, the DRAM 515 may be accessed by the baseband processor 513 through a first channel and may be accessed by an application processor through a second channel. Thus, a memory chip may be shared by two processors.

Although the example shown FIG. 13 includes the DRAM 515, in other embodiments the DRAM 515 may be replaced with an MRAM.

A volatile semiconductor memory device such as an SRAM or a DRAM may lose data stored therein when power to the volatile semiconductor memory device is interrupted.

On the contrary, a nonvolatile semiconductor memory device such as an MRAM may retain data stored therein even when power to the volatile semiconductor memory device is interrupted. Thus, a nonvolatile semiconductor memory device may be used to store data when data has to be retained through a power failure or power interruption.

A multi-channel memory device may be formed of an STT-MRAM (Spin Transfer Torque Magnetoresistive Random Access Memory). An STT-MRAM cell may include an MTJ (Magnetic Tunnel Junction) element and a selection transistor. The MTJ element may include a fixed layer, a free layer, and a tunnel layer interposed between the fixed layer and the free layer. A magnetization direction of the fixed layer may be fixed, and a magnetization direction of the free layer may be opposite to or the same as that of the fixed layer, depending on a condition.

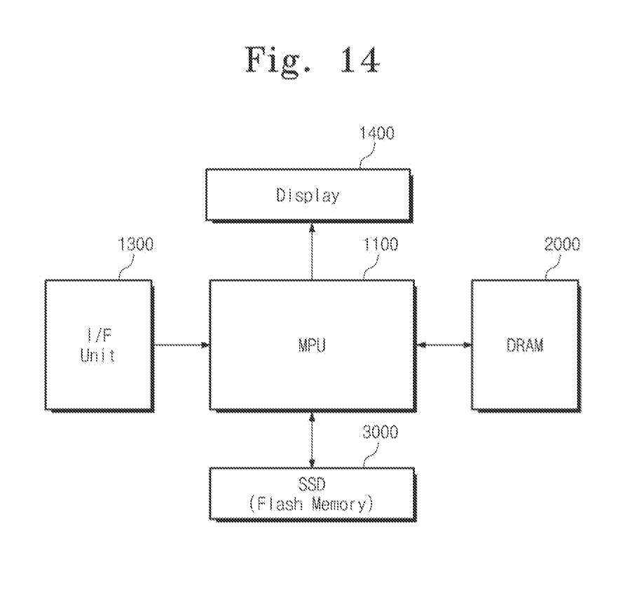

FIG. 14 is a schematic block diagram that illustrates an application of an embodiment of the inventive concept to a mobile device.

Referring to FIG. 14, a mobile device, such as a notebook computer or a portable electronic device, may include a micro processing unit (MPU) 1100, a display 1400, an interface (I/F) unit 1300, a DRAM 2000, and a solid state drive (SSD) flash memory 3000.

In some cases, the MPU 1100, the DRAM 2000, and the SSD 3000 may be integrated or packaged in a chip. That is, the DRAM 2000 and the flash memory 3000 may be embedded in the mobile device.

If the mobile device is a portable communications device, the interface unit 1300 may be connected to a modem and transceiver block which is configured to transmit and receive communication data and to modulate and demodulate data.

The MPU 1100 may control an overall operation of the mobile device according to a given program.

The DRAM 2000 may be connected to the MPU 1100 through a system bus and may be used as a buffer memory or a main memory of the MPU 1100.

The DRAM 2000 may be a multi-channel memory device such as that shown in FIG. 1.

The flash memory 3000 may include a NOR or NAND flash memory.

The display unit 1400 may have be liquid crystal display that has a backlight, a liquid crystal display that has an LED light source, or a touch screen, such as an OLED. The display unit 1400 may be an output device for displaying images, including characters, numbers, pictures, etc., in color.

Embodiments of the inventive concept have been described under an assumption that the mobile device is a mobile communications device. In some cases, the mobile device may function as a smart card by adding or removing components to or from the mobile device.

A mobile device may be connected to an external communication device through a separate interface. The external communication device may be a DVD (Digital Versatile Disc) player, a computer, a set top box (STB), a game machine, a digital camcorder, etc.

In addition, a mobile device may further include an application chipset, a camera image processor, a mobile DRAM, etc.

Although FIG. 14 illustrates an embodiment in which a flash memory is used, embodiments of the inventive concept are not limited thereto. For example, a variety of nonvolatile storages may be used.

A nonvolatile storage may store data information in various data formats, such as a text, graphics, software code, etc.

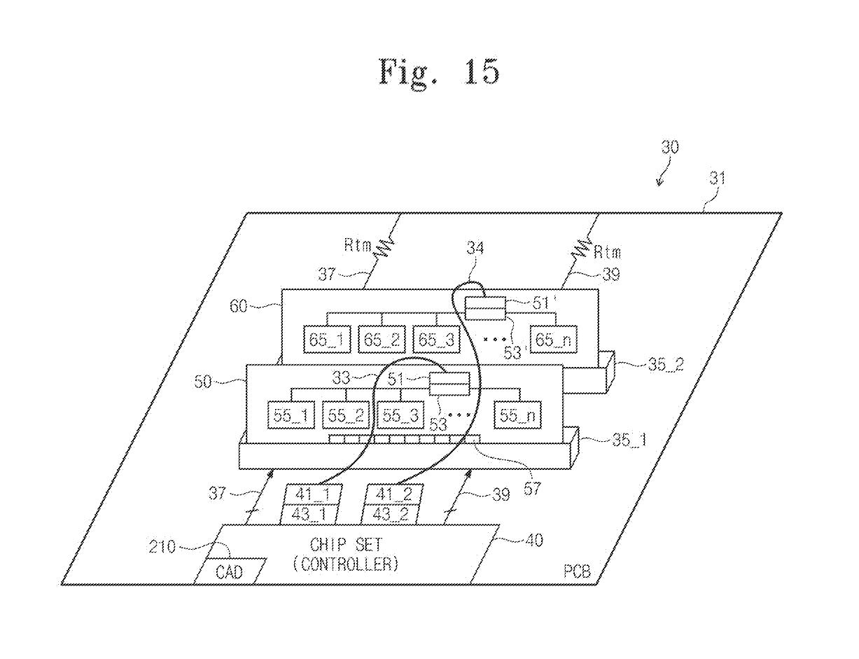

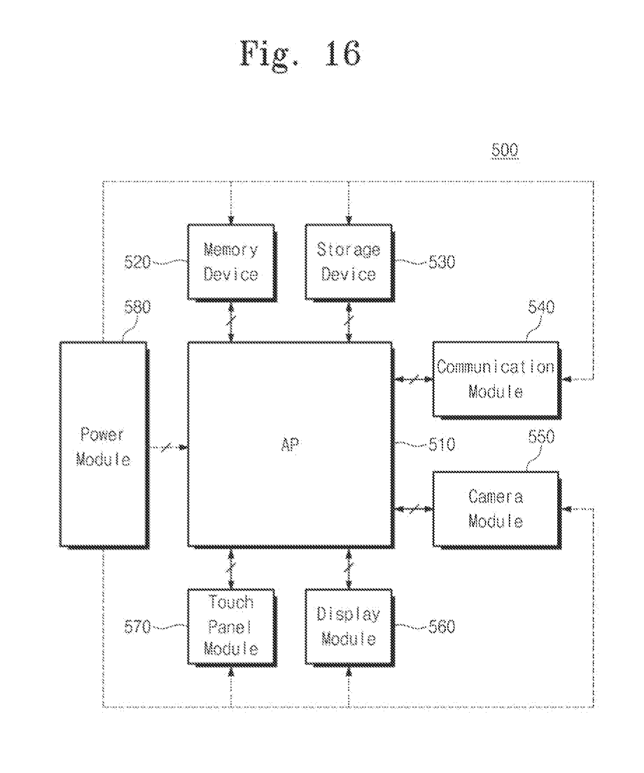

FIG. 15 is a schematic block diagram that illustrates an application of an embodiment of the inventive concept to an optical I/O scheme.

Referring to FIG. 15, a memory system 30 that uses a high-speed optical input/output scheme may include a chipset 40 as a controller and memory modules 50 and 60, and the components 40, 50, and 60 may be mounted on a printed circuit board (PCB) substrate 31. The memory modules 50 and 60 may be inserted in slots 35_1 and 35_2 installed on the PCB substrate 31. The memory module 50 may include a connector 57, channel DRAM memories 55_1 to 55_{—}n, an optical I/O input unit 51, and an optical I/O output unit 53. In addition, the memory module 60 may include a connector, channel DRAM memories 65_1 to 65_{—}n, an optical I/O input unit 51′, and an optical I/O output unit 53′.

The optical I/O input units 51. 51′ may include a photoelectric conversion element, such as a photodiode, to convert an input optical signal into an electrical signal. The electrical signal output from the photoelectric conversion elements may be received by the memory modules 50 or 60. The optical I/O output unit 53, 53′ may include an electro-photic conversion element, such as a laser diode, to convert an electrical signal received from the memory modules 50 or 60 into an optical signal. In some cases, the optical I/O output units 53, 53′ may further include an optical modulator to modulate a signal received from a light source.

An optical cable 33 may perform optical communications between the optical I/O input unit 51 of the memory module 50 and an optical transmission unit 41_1 of the chipset 40. Similarly, an optical cable 34 may perform optical communications between the optical I/O input unit 51′ of the memory module 60 and an optical transmission unit 41_2 of the chipset 40. The optical communications may have a bandwidth of, for example, more than a score gigabits per second. The memory modules 50 and 60 may receive signals or data from signal lines 37 and 39 of the chipset 40 through the connector 57, and may perform high-speed data communications with the chipset 40 through the optical cables 33 and 34. In addition, resistances Rtm installed at lines 37 and 39 may be termination resistances.

In the memory system 30 with an optical I/O structure according to an embodiment of the inventive concept such as that shown in FIG. 15, the channel DRAM memories 55-1 to 55-n and 65_1 to 65_{—}n may be mounted within a chip.

Thus, the chipset 40 may perform a data read operation and a data write operation independently for every channel through the channel DRAM memories 55-1 to 55-n and 65_1 to 65_{—}n. In this case, as illustrated in FIG. 1, a power network may be implemented independently. Thus, channel power noise may not affect an adjacent channel, so the performance of the memory system 30 may be improved or stabilized.

In FIG. 15, the chipset 40 may include a concentration access detecting (CAD) unit 210. The concentration access detecting unit 210 may generate a concentration access detection signal when an input frequency of a frequently received address exceeds a threshold value.

When the concentration access detection signal is generated, the chipset 40 may alleviate of prevent corruption of data of memory cells adjacent to a specific memory area.

For example, if a specific word line, bit line or memory block of a volatile semiconductor memory, such as DRAM, is frequently accessed, cell data may be corrupted. That is, cell data of memory cells of word lines adjacent to a specific word line, bit lines adjacent to a specific bit line, or a memory block adjacent to a specific memory block may be lost due to frequent accesses. Loss of cell data may be prevented or alleviated by avoiding frequent address accesses.

If the channel DRAM memories 55-1 to 55-n of the memory modules 50 and 60 are accessed by a memory page unit, a column unit or a bank unit, the concentration access detecting unit 210 may monitor access frequency or concentration.

If the memory system 30 shown FIG. 15 is an SSD, the channel DRAM memories 55_1 to 55_{—}n may be used as a user data buffer.

FIG. 16 is a schematic block diagram that illustrates an application of an embodiment of the inventive concept to a portable multimedia device.

Referring to FIG. 16, a portable multimedia device 500 may include an application processor (AP) 510, a memory device 520, a storage device 530, a communication device 540, a camera module 550, a display module 560, a touch panel module 570, and a power module 580.

The AP 510 may perform a data processing function.

In FIG. 16, the memory device 520 may be configured such that a power network is implemented to be independent of a channel as described with reference to FIG. 1. Thus, since channel power noise does not affect an adjacent channel, the performance of the portable multimedia device may be improved or stabilized. Also, in some cases, a power network may be formed in the memory device 520.

The communication module 540 connected to the AP 510 may be a modem that transmits and receives communication data and modulates and demodulates data.

The storage device 530 may be implemented by a NOR or NAND flash memory.

The display module 560 may be a liquid crystal display that has a backlight, a liquid crystal that has an LED light source, or a touch screen, such as an OLED). The display module 560 may be used as an output device for displaying images, including characters, numbers, pictures, etc., in color.

The touch panel module 570 may provide the AP 510 with a touch input independent of or on the display module 560.

Embodiments of the inventive concept have been described under the assumption that the portable multimedia device is a mobile communications device. However, in some cases, the portable multimedia device may function as a smart card by adding or removing components to or from the mobile device.

A portable multimedia device may be connected to an external communications device through a separate interface. The external communications device may be a DVD (Digital Versatile Disc) player, a computer, a set top box (STB), a game machine, a digital camcorder, etc.

The power module 580 may manage power of the portable multimedia device. Thus, in the event that a power management integrated circuit (PMIC) scheme is applied to a device, power of the portable multimedia device may be saved.

The camera module 550 may include a camera image processor and may be connected to the AP 510.

In addition, the portable multimedia device may further include an application chipset, a mobile DRAM, etc.

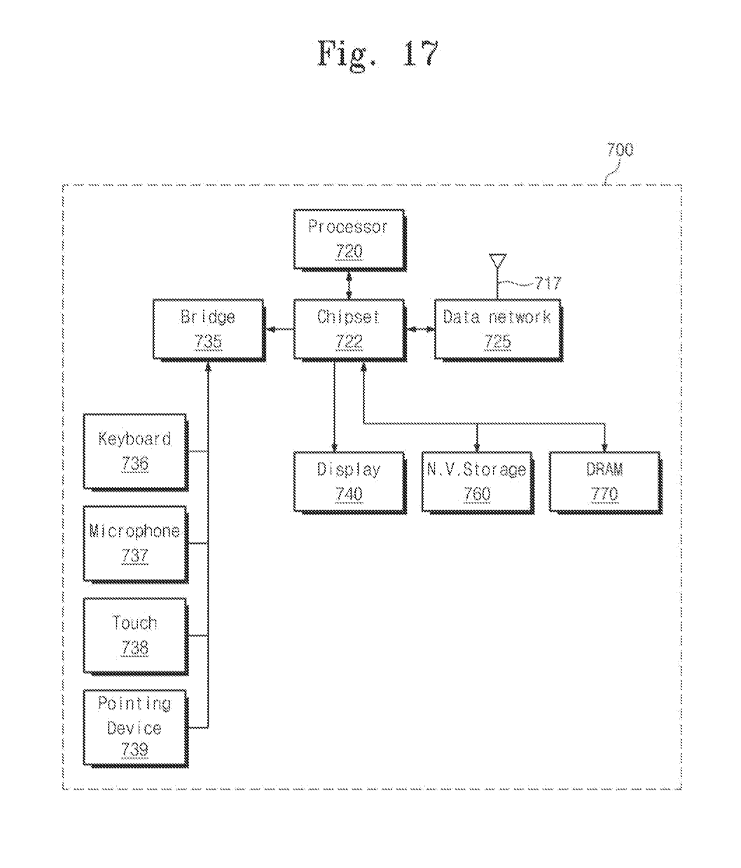

FIG. 17 is a schematic block diagram that illustrates an application of an embodiment of the inventive concept to a personal computer. Referring to FIG. 17, a computing device 700 may include a processor 720, a chipset 722, a data network 725, a bridge 735, a display 740, nonvolatile (N.V.) storage 760, a DRAM 770, a keyboard 736, a microphone 737, a touch unit 738, and a pointing device 739.

In FIG. 17, the DRAM 770 may form a power network to be independent of a channel as described with reference to FIG. 1. Thus, since channel power noise may not affect an adjacent channel, the performance of the personal computer 700 may be improved or stabilized.

The chipset 722 may provide the DRAM 770 with a command, an address, data, or a control signal.

The processor 720 may function as a host and may control an overall operation of the personal computer 700.

A host interface between the processor 720 and the chipset 722 may include various protocols for performing data communications.

The nonvolatile storage 760 may be an EEPROM (Electrically Erasable Programmable Read-Only Memory), a flash memory, a MRAM (Magnetic RAM), a STT-MRAM (Spin-Transfer Torque MRAM), a CBRAM (Conductive bridging RAM), a FeRAM (Ferroelectric RAM), a PRAM (Phase change RAM), an OUM (Ovonic Unified Memory), a RRAM or ReRAM (Resistive RAM), a nanotube RRAM, a PoRAM (Polymer RAM), a NFGM (Nano Floating Gate Memory), a holographic memory, a molecular electronics memory device, or an insulator resistance change memory.

The personal computer shown in FIG. 17 may be used as one of the various components of an electronic device such as a computer, a ultra-mobile personal computer (UMPC), a workstation, a net-book, a personal digital assistance (PDA), a portable computer (PC), a web tablet, a wireless phone, a mobile phone, a smart phone, a smart television, a three-dimensional television, an e-book, a portable multimedia player (PMP), a portable game console, a navigation device, a black box, a digital camera, a digital multimedia broadcasting (DMB) player, a digital audio recorder, a digital audio player, a digital picture recorder, a digital picture player, a digital video recorder, a digital video player, a device for transmitting and receiving information in a wireless environment, one of the various electronic devices constituting a home network, one of the various electronic devices constituting a computer network, one of the various electronic devices constituting a telematics network, a radio frequency identification (RFID) device, and one of the various components constituting a computing system.

While embodiments of the inventive concept have been described with reference to exemplary embodiments, it will be apparent to those skilled in the art that various changes and modifications may be made without departing from the spirit and scope of the exemplary embodiments. Therefore, it should be understood that the above embodiments are not limiting, but illustrative.

For example, embodiments of the inventive concept have been described as using first and second channel memories. In some cases, changes or modification on a detailed implementation of power network may be made by changing circuit components of drawings or adding or subtracting components without departing from the spirit and scope of the present invention. In addition, embodiments of the inventive concept have been described using a memory system that includes a DRAM. However, embodiments of the inventive concept are applicable to other semiconductor memory devices that can detect a current difference without a current mirroring operation.

What is claimed is:

1. A multi-channel memory device comprising:
a first channel memory and a second channel memory that are independently accessible within a same chip and that respectively include first and second external power channel connection lines;
a decoupling unit configured to operationally connect or separate the first and second external power channel connection lines in response to a decoupling driving signal; and
a switching control unit configured to apply the decoupling driving signal to the decoupling unit in response to a channel power control signal wherein external power supply voltages independently applied to the first and second channel memories are respectively used in corresponding first and second external power channel connection lines.

2. The multi-channel memory device of claim 1, wherein each of the first and second channel memories comprises one of a DRAM cell or an MRAM cell.

3. The multi-channel memory device of claim 1, wherein the first and second external power channel connection lines are connected to each other when a corresponding switch of the decoupling unit is closed.

4. The multi-channel memory device of claim 1, wherein the first and second external power channel connection lines are separated from each other when a corresponding switch of the decoupling unit is opened.

5. The multi-channel memory device of claim 1, wherein when the decoupling unit is activated, the first channel memory and the second channel memory form a power network over the multi-channel memory device.

6. The multi-channel memory device of claim 1, wherein the decoupling unit is one of an RC filter or a transmission gate.

7. The multi-channel memory device of claim 1, further comprising external power supply pads, wherein the first and second external power channel connection lines receive the external supply voltages through said external power supply pads, wherein an external power supply pad is installed for each channel, and the external power supply pads are connected in common to an external power common pad.

8. A multi-channel memory device comprising:
a first channel memory and a second channel memory that are independently accessible within a same chip and that include first and second internal power channel connection lines;
first and second internal power generators configured to apply first and second internal power supply voltages that are independent of each other to the first and second channel memories;
a decoupling unit configured to operationally connect or separate first and second internal power channel connection lines in response to a decoupling driving signal; and
a switching control unit configured to apply the decoupling driving signal to the decoupling unit in response to a channel power control signal wherein the first and second internal power supply voltages are respectively used in corresponding first and second internal power channel connection lines.

9. The multi-channel memory device of claim 8, wherein each of the first and second internal power generators generates an internal power supply voltage, a high power supply voltage that is greater than the internal power supply voltage, or a substrate power supply voltage that is less than the internal power supply voltage.

10. The multi-channel memory device of claim 8, wherein each of the first and second channel memories comprises a plurality of DRAM cells, each having an access transistor and a storage capacitor.

11. The multi-channel memory device of claim 8, wherein when a corresponding switch of the decoupling unit is closed, the first and second internal power channel connection lines are connected to each other, and a power network is formed over the first and second channel memories.

12. The multi-channel memory device of claim 8, wherein when a corresponding switch of the decoupling unit is opened, the first and second internal power channel connection lines are separated from each other, and the first and second channel memories have independent power networks, respectively.

13. The multi-channel memory device of claim 12, wherein a DC component of the first and second internal power supply voltages is shorted, and an AC component of the first and second internal power supply voltages is opened.

14. The multi-channel memory device of claim 8, wherein the multi-channel memory device is mounted on a mobile device.

15. The multi-channel memory device of claim 8, wherein the channel power control signal is provided as a mode register set signal at power-up of the multi-channel memory device.

16. A method of controlling a power network of a multi-channel memory device, the method comprising:
applying first and second power supply voltages to first and second channel memories of the multi-channel memory device that respectively correspond to the first and second power supply voltages; and
operationally separating first and second power networks of the first and second channel memories when a decoupling request signal is generated,
wherein the first and second channel memories are independently accessible within a same chip, and the first and second power supply voltages are independent of each other.

17. The method of claim 16, wherein the first and second power supply voltages are internal power supply voltages.

18. The method of claim 16, wherein the first and second power supply voltages are external power supply voltages.

19. The method of claim 16, further comprising operationally connecting said first and second power networks of the first and second channel memories when a decoupling switch is closed, wherein a power network is formed over the first and second channel memories.
